(19) United States
(12) Patent Application Publication
(10) Pub. No.: US 2013/0234288 A1
(43) Pub. Date: Sep. 12, 2013

(54) Trench Structure for an MIM Capacitor and Method for Manufacturing the Same

(71) Applicants: Sung Mo GU, Seoul (KR); Moon Hyung CHO, Seoul (KR); Young Sang KIM, Seoul (KR); Jong Bum PARK, Seoul (KR)

(72) Inventors: Sung Mo GU, Seoul (KR); Moon Hyung CHO, Seoul (KR); Young Sang KIM, Seoul (KR); Jong Bum PARK, Seoul (KR)

(21) Appl. No.: 13/614,893

(22) Filed: Sep. 13, 2012

(30) Foreign Application Priority Data
Mar. 6, 2012 (KR) 10-2012-0022742

(51) Int. Cl. H01L 29/92; H01L 21/02

(52) U.S. Cl. 257/532; 438/387; 257/E21.011; 257/E29.343

(57) ABSTRACT

A method for manufacturing a MIM capacitor trench structure includes forming a lower metal film on an inter-metal dielectric; forming a first inter-metal dielectric on the lower metal film; forming a first trench; sequentially forming a dielectric film and a first barrier metal film along the bottom surface and sidewalls of the first trench; and filling the first trench with a conductive material to form a first upper metal film. Further, the method includes forming a second inter-metal dielectric on the first upper metal film; forming a second trench; forming a via hole in a via hole region of the second inter-metal dielectric; forming a second barrier metal film along the bottom surface and sidewalls of the second trench; and filling the via hole and the second trench with the conductive material to form a via contact and a second upper metal film.

### RELATED APPLICATIONS

This application claims the benefit of Korean Patent Application No. 10-2012-0022742, filed on Mar. 6, 2012, which is hereby incorporated by reference as if fully set forth herein.

### FIELD OF THE INVENTION

The present invention relates to a semiconductor device and a method for manufacturing the same; and more particularly, to a trench structure for an upper electrode of a metal-insulator-metal (MIM) capacitor and a method for manufacturing the same. The present invention includes forming an upper metal film of a capacitor through a two-step etching and filling process to form an upper metal electrode comprising a conductive material. The presently disclosed methods include forming a first trench and filling the first trench with a conductive material, and then forming a second trench and filling the second trench with a conductive material. The presently disclosed methods for manufacturing the trench structure MIM capacitor reduce or prevent the occurrence of a dishing phenomenon in which the upper metal film of the MIM capacitor is excessively etched due to an excessive thickness of the upper metal film and large surface area of the MIM capacitor.

### BACKGROUND OF THE INVENTION

In general, polysilicon-insulator-polysilicon (PIP) capacitors and MIM capacitors are used in logic circuits of a semiconductor device, since these capacitors are separated from bias, unlike a metal oxide semiconductor (MOS) capacitor or a junction capacitor.

In a PIP capacitor, since a lower electrode and an upper electrode are formed of polysilicon, a natural oxide film is formed in the interface between the electrodes and the insulator thin film. The natural oxide film causes leakage current, resulting in a decrease in capacitance of the capacitor.

On the other hand, an MIM capacitor has low resistivity and no parasitic capacitance due to depletion, and excellent voltage coefficient and temperature coefficient characteristics, compared to a PIP capacitor. Accordingly, the MIM capacitor is often used in high-performance circuits, such as logic, CIS (CMOS Image Sensor), and DDI (Display Driver IC).

In order to increase capacitance, the MIM capacitor is formed by forming a wide and relatively deep trench in an inter-metal dielectric, forming an insulating film serving as a dielectric film of the capacitor in the trench, and forming a conductive material serving as an upper metal film on the insulating film.

However, in the conventional trench structure of an MIM capacitor, the upper metal film is excessively etched due to relatively large variations in its thickness and the wide area when planarizing the conductive material in the trench. As a result, dishing is caused in the upper surface of the upper metal film.

FIGS. 1A to 1D show a process of manufacturing a conventional trench structure MIM capacitor. The process of manufacturing the conventional trench structure will be described with reference to FIGS. 1A to 1D.

First, as shown in FIG. 1A, a lower metal film 102 is formed on an inter-metal dielectric (IMD) 100 formed on a semiconductor substrate, and an inter-metal dielectric (IMD) 104 is formed on the lower metal film 102. Next, as shown in FIG. 1B, a trench is formed in an MIM capacitor region of the inter-metal dielectric 104 by photolithography.

Next, as shown in FIG. 1C, a dielectric film 106 and a barrier metal film 108 are sequentially formed on the surfaces of the inter-metal dielectric 104 and the lower metal film 102, and a conductive material 110, such as tungsten (W), is deposited to fill in the trench.

Next, as shown in FIG. 1D, the conductive material 110 in the trench is planarized by chemical mechanical polishing (CMP) to form an upper metal film 110′ of the MIM capacitor. A via hole 114 may be formed by photolithographic patterning and etching a region of the inter-metal dielectric 104 separate from the lower metal film 102 of the MIM capacitor by a predetermined distance. Accordingly, the trench structure MIM capacitor having the lower metal film 102, the dielectric film 106, and the upper metal film 110′ is formed, and a conductive material, such as tungsten, is filled in the via hole 114 through a subsequent process for forming a via contact.

However, since the trench in a conventional MIM capacitor has a relatively great depth, the metal film 110 (FIG. 1C) has a relatively great variation in its thickness, so the metal film 110 must be overpolished for a relatively long time to remove all of the metal outside the trenches. Also, due to the large surface area of the conventional MIM trench structure shown in FIG. 1D, the upper metal film 110′ is excessively etched when the conductive material in the trench, such as tungsten, is planarized, thereby causing dishing 112 in the upper surface of the conductive material.

### SUMMARY OF THE INVENTION

The invention provides a trench structure for reducing dishing in an upper metal film of a metal-insulator-metal (MIM) capacitor and a method for manufacturing a MIM capacitor in which an upper metal film of a capacitor is formed through a two-step process, where each step includes etching a dielectric layer to form a trench and filling the trench with a conductive material. The presently disclosed trench structure for an MIM capacitor reduces or prevents the occurrence of a dishing phenomenon in which the upper metal film of the MIM capacitor is excessively etched during a CMP process. Such dishing occurs in convention MIM capacitors due to a large depths and widths of the upper electrode and large surface areas of the MIM capacitor.

In accordance with a first aspect of the present invention, there is provided a method for manufacturing a trench structure for an MIM capacitor, including: forming a lower metal film on or in an underlying inter-metal dielectric on a semiconductor substrate; forming a first inter-metal dielectric on the lower metal film; forming a first trench in a capacitor region of the first inter-metal dielectric; sequentially forming a dielectric film and a first barrier metal film along the bottom surface and sidewalls of the first trench; filling the first trench with a first conductive material to form a first upper metal film; forming a second inter-metal dielectric on the first upper metal film; forming a second trench in the second inter-metal dielectric in the capacitor region; forming a via hole in a via hole region of the first and second inter-metal dielectrics that is separated from the first upper metal film by a pre-determined distance; forming a second barrier metal film along the bottom surface and sidewalls of the second trench; and filling the via hole and the second trench with a second conductive material to form a via contact and a second upper metal film.

Further, the first trench may expose the lower metal film, and the second trench may expose the first upper metal film.

Further, forming the first upper metal film may include filling the first trench with the first conductive material and planarizing the upper surface of the conductive material (e.g., until an upper surface of the first inter-metal dielectric is exposed) to form the first upper metal film.

Further, forming the second upper metal film may include filling the second trench and the via hole with the second conductive material and planarizing the upper surface of the second conductive material (e.g., until an upper surface of the second inter-metal dielectric is exposed) to form the second upper metal film and the via contact.

Further, the first and second trenches may each have a width of about 50 μm to about 100 μm (e.g., about 60 μm to about 90 μm, about 65 μm to about 85 μm, or any value or range of values therein). Additionally, the first and second trenches may have a same width and may be aligned.

Further, the first and second barrier metal films may comprise a titanium/titanium nitride film (Ti/TiN). In another embodiment, the first and second third inter-metal dielectrics may be a same material (e.g., silicon oxide, silicon nitride, or silicon oxynitride).

Further, the first and second upper metal films may comprise tungsten (W). Furthermore, the via contact may comprise tungsten (W).

A second aspect of the present invention relates to a trench structure for an MIM capacitor including: a lower metal film on or in an underlying inter-metal dielectric on a semiconductor substrate; a first inter-metal dielectric on the lower metal film; a first trench in the first inter-metal dielectric layer over the lower metal film in a capacitor region of the semiconductor substrate; a dielectric film on sidewalls and a bottom of the first trench; a first barrier metal film on the surface of the dielectric film; a first upper metal film in the first trench and over the first barrier metal film; a second inter-metal dielectric on the first upper metal film; a second trench in the second inter-metal dielectric, over the first upper metal film and in the capacitor region; a second barrier metal film on the second inter-metal dielectric; and a second upper metal film in the second trench and over the second barrier metal film.

The trench structure MIM capacitor may further comprise a via contact through the first and second inter-metal dielectrics, separated from the first upper metal film by a pre-determined distance of about 5 μm to about 100 μm (e.g., about 10 μm to about 90 μm, about 25 μm to about 75 μm, or any value or range of values therein).

Further, the first and second trenches may each have a width of about 50 μm to about 100 μm (e.g., about 60 μm to about 90 μm, about 65 μm to about 85 μm, or any value or range of values therein). Additionally, the first and second trenches may have a same width and may be aligned.

Further, the first and second barrier metal films may comprise a titanium/titanium nitride film (Ti/TiN).

Further, the first and second upper metal films may comprise tungsten (W). Furthermore, the via contact may comprise tungsten (W). In another embodiment, the first and second inter-metal dielectrics may comprise a same material (e.g., silicon oxide, silicon nitride, or silicon oxynitride).

In accordance with embodiments of the present invention, an upper metal film of an MIM capacitor may be formed in a trench by a two-step process, where each step includes etching an inter-metal dielectric to form a trench and then filling the trench with a conductive material. The presently disclosed structure and method(s) for forming an upper metal film in a metal-insulator-metal capacitor reduce or prevent dishing, in which the upper metal film of the MIM capacitor is excessively etched during CMP due to relatively large variations in the thickness of the deposited metal film for forming the upper electrode and the large surface area of the MIM capacitor.

### BRIEF DESCRIPTION OF THE DRAWINGS

The above and other features of the present invention will become apparent from the following description of an embodiment given in conjunction with the accompanying drawings, in which:

FIGS. 1A to 1D illustrate steps in an exemplary process for manufacturing a conventional trench structure for an MIM capacitor; and

FIGS. 2A to 2I illustrate steps in an exemplary process for manufacturing a trench structure for an MIM capacitor in accordance with embodiments of the invention.

### DETAILED DESCRIPTION OF THE EMBODIMENTS

Hereinafter, embodiments of the present invention will be described in detail, with reference to the accompanying drawings which form a part hereof.

The advantages and features of the present invention can be clearly understood from the following descriptions of various embodiments and the accompanying drawings. However, the following description is intended to cover alternatives, modifications, and equivalents that may be included within the spirit and scope of the present invention, and omits already known structures and operations if it may confuse or obscure the subject matter of the present invention. The following terms are used in the context of embodiments of the present invention, but are not limiting and may be interchangeable with other terms used in the relevant art.

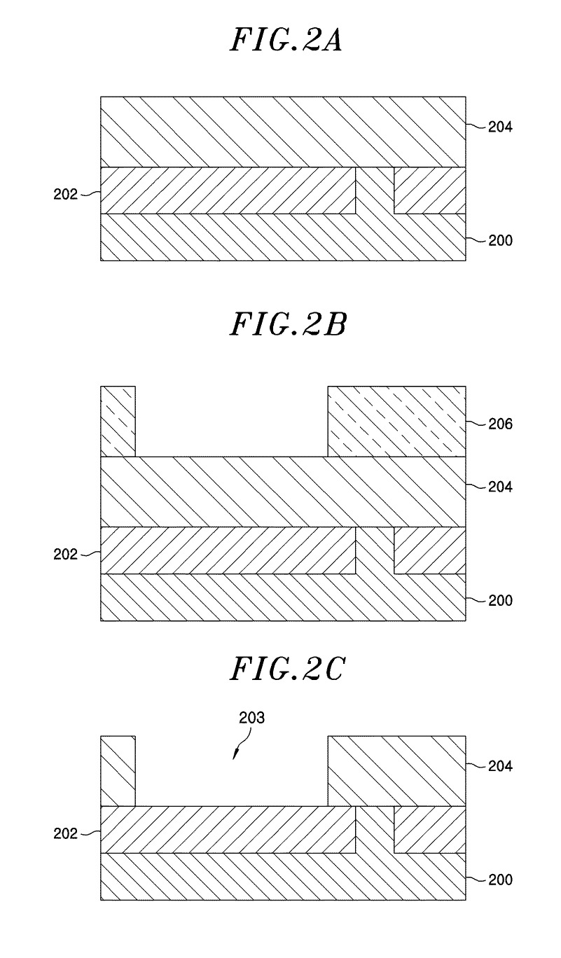

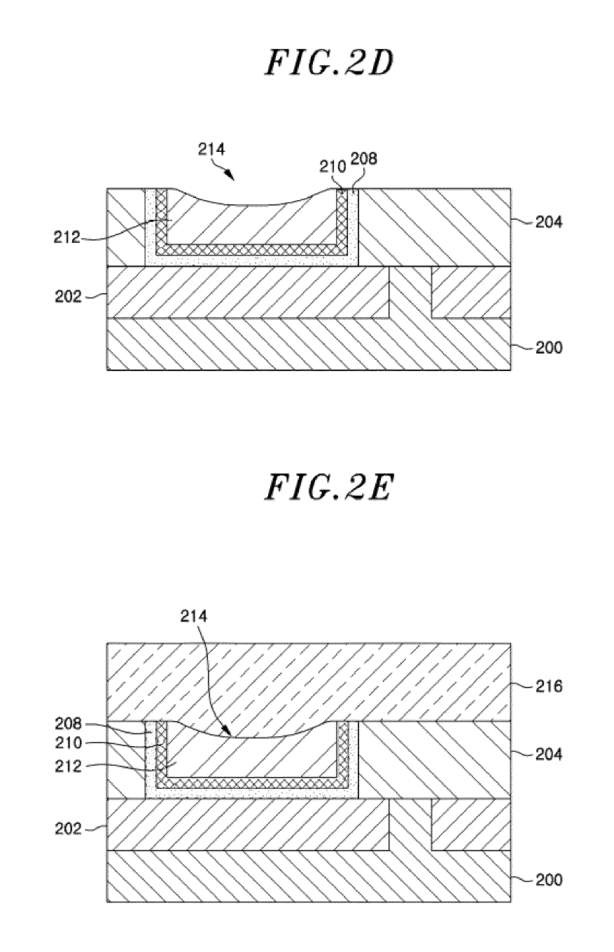

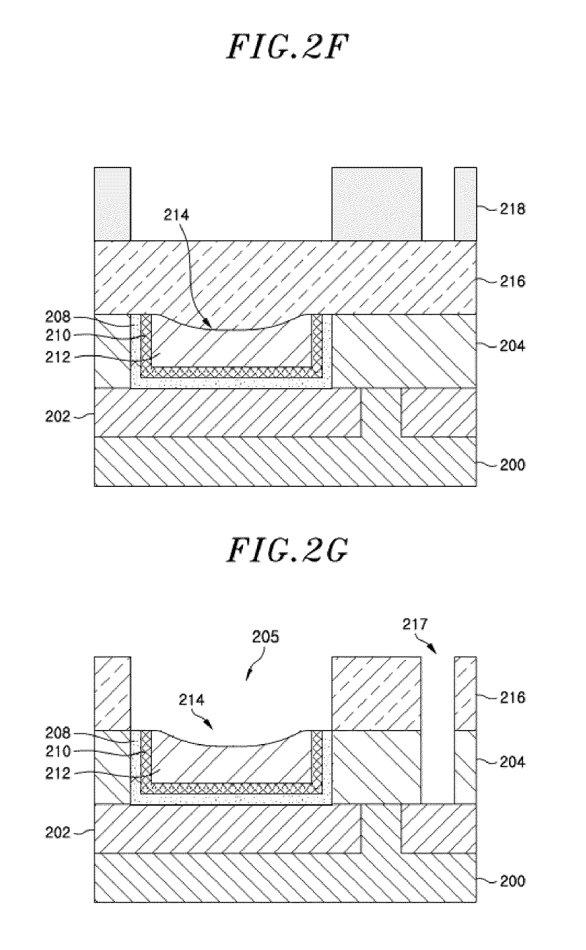

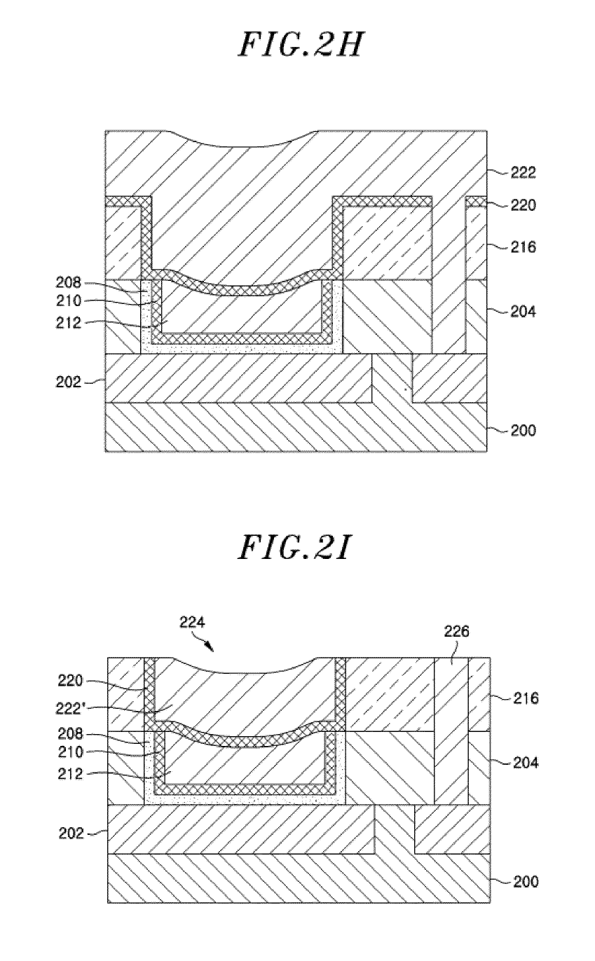

FIGS. 2A to 2I illustrate exemplary processes for manufacturing a trench structure and/or an upper metal layer of an MIM capacitor in accordance with embodiments of the invention. Such processes for manufacturing the trench structure of an MIM capacitor in accordance with the present invention are described below in detail with reference to FIGS. 2A to 2I.

First, as shown in FIG. 2A, a lower metal film 202 (e.g., comprising tungsten, titanium, titanium nitride, tantalum, tantalum nitride, aluminum, copper, ruthenium, or a combination thereof) is formed in or on a first inter-metal dielectric 200 (e.g., comprising one or more layers of doped or undoped silicon dioxide, silicon nitride, silicon oxynitride, etc.) formed on a semiconductor substrate. Subsequently, a second inter-metal dielectric 204 (e.g., comprising one or more layers of doped or undoped silicon dioxide, silicon nitride, silicon oxynitride, etc.) is formed on the lower metal film 202. Next, as shown in FIG. 2B, a photoresist film is coated on the second inter-metal dielectric 204 and patterned through photolithography to form a photoresist mask 206 to define an MIM capacitor region and expose a portion of the second inter-metal dielectric 204 in the capacitor region. The photoresist mask 206 also defines a first trench region in the MIM capacitor region where an MIM capacitor will be formed.

Next, as shown in FIG. 2C, the first inter-metal dielectric 204 may be etched (e.g., by dry chemical, plasma or reactive ion etching) using the photoresist mask 206 as a mask such that the lower metal film 202 is exposed. Thus, a first trench 203 is formed in the MIM capacitor region of the first inter-metal dielectric 204. The first trench 203 may have a depth in a range of about 0.5 μm to 10 μm (e.g., about 1 μm to about 5 μm, about 1.25 μm to about 4 μm, or any value or range of values therein).

Next, as shown in FIG. 2D, a dielectric film 208 (e.g., a capacitor dielectric comprising one or more layers of doped or undoped silicon oxide, silicon nitride, silicon oxynitride, a high-k dielectric such as aluminum oxide, tantalum oxide, or hafnium oxide, or combinations thereof) and a first barrier metal film 210 are sequentially formed along the sidewalls of the second inter-metal dielectric 204 and a top surface of the lower metal film 202. For example, the dielectric film 208 may be formed on and may cover the bottom surface and the sidewalls of the first trench 203, and the first barrier metal film 210 may be formed on and may cover the dielectric film 208. A conductive material, such as tungsten, may then be deposited (e.g., by physical vapor deposition [PVD] or chemical vapor deposition [CVD]) over the dielectric film 208 and the first barrier metal film 210 to fill in the first trench 203. Subsequently, the conductive material may be planarized through a CMP planarization to form a first upper metal film 212 of the MIM capacitor. The width of the first trench 203 may be in a range of about 50 μm to 100 μm (e.g., about 60 μm to about 90 μm, about 65 μm to about 85 μm, or any value or range of values therein), and the thickness of the first upper metal film as deposited may be in a range of about 1 μm to 20 μm (e.g., about 2 μm to about 10 μm, about 2.5 μm to about 8 μm, or any value or range of values therein). The first barrier metal film 210 may be or may comprise a titanium/titanium nitride (Ti/TiN) film.

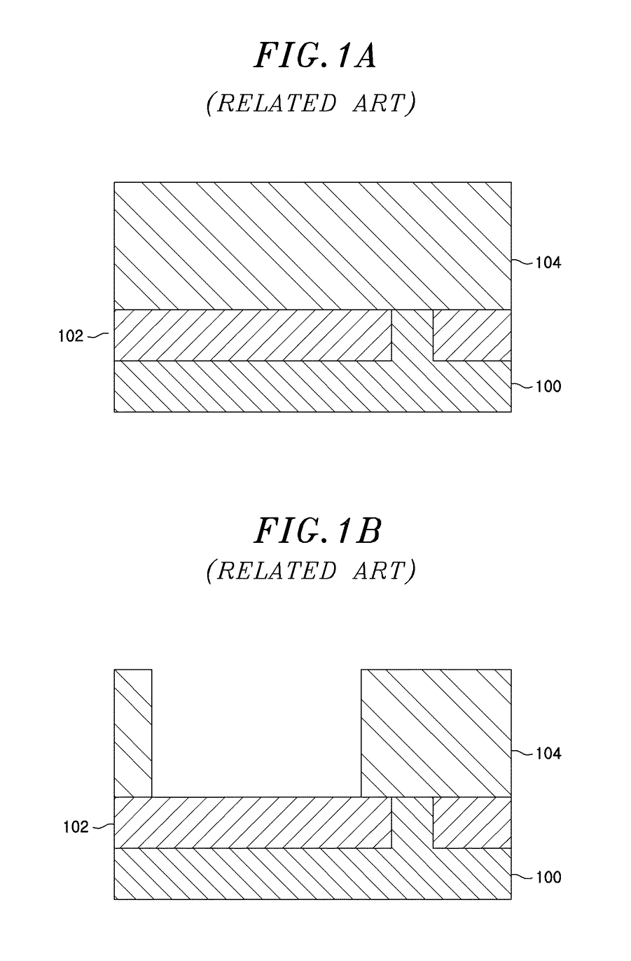

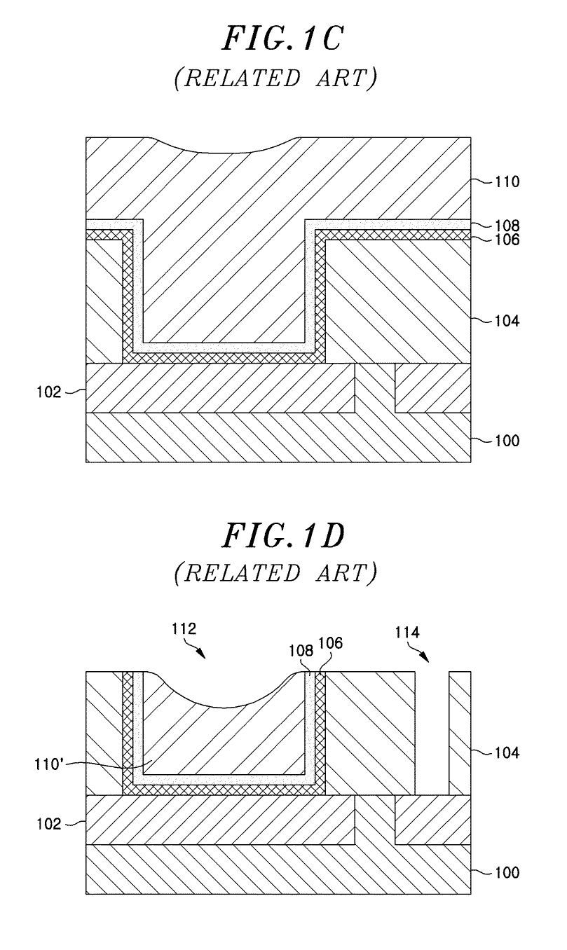

As shown in FIG. 2D, the first upper metal film 212 formed in the above-described manner may be overetched during the CMP planarization. On the other hand, in accordance with the invention, a second trench and additional conductive material may be formed in a stepwise manner over the first upper metal film 212 in order to reduce dishing in the upper electrode of the MIM capacitor. Specifically, dishing occurs at a relatively small depth in the first upper metal film 212 because the first trench 203 shown in FIG. 2C has a comparatively small depth compared to the relatively deep trench of conventional MIM capacitors. Therefore, the layer of conductive material formed in the first trench 203 has relatively less variation in its thickness compared to the metal film 110 shown in FIG. 1C. Consequently, less over-polishing is required to remove excess conductive material outside of the first trench 203.

Next, as shown in FIG. 2E, a third inter-metal dielectric 216 (e.g., comprising one or more layers of doped or undoped silicon dioxide, silicon nitride, silicon oxynitride, etc.) is formed on the first upper metal film 212. As shown in FIG. 2F, a photoresist film is coated on the third inter-metal dielectric 216 and patterned by photolithography to form a photoresist mask 218 defining a second trench in the MIM capacitor region and a via hole that is spaced or separated by a pre-determined distance from the lower metal layer 202. The photoresist mask 218 may define the second trench in such a way that it is aligned with the first trench 203 and has a same width as the first trench 203. Additionally, edges or borders of the photoresist mask 218 may overlap with the dielectric layer 208 to prevent second dielectric layer 204 from being etched when the third inter-metal dielectric 216 is patterned.

Next, as shown in FIG. 2G, the third inter-metal dielectric 216 is etched (e.g., by plasma etching or reactive ion etching) using the photoresist mask 218 such that the first upper metal film 212 is exposed. Thus, a second trench 205 is formed in the MIM capacitor region in the third inter-metal dielectric 216, and the third inter-metal dielectric 216 and the second inter-metal dielectric 204 in a via hole forming region are etched to form a via hole 217. The second inter-metal dielectric 204 and the third inter-metal dielectric 216 may comprise the same material (e.g., silicon dioxide, silicon nitride, or silicon oxynitride) to facilitate the formation of the via hole 217 in a single etching step. In other embodiments, a second etching step (e.g., with a different etchant or etchant mixture) may be performed for etching through the second inter-metal dielectric 204 to form the via hole. Additionally, the dielectric layer 208 may comprise a different material than the second inter-metal dielectric 204 and the third inter-metal dielectric 216, and thus may not be etched significantly during the etching step(s) for forming the second trench 205 and the via hole 217. The second trench 205 may have a depth in a range of about 0.5 μm to 10 μm (e.g., about 1 μm to about 5 μm, about 1.25 μm to about 4 μm, or any value or range of values therein).

Next, as shown in FIG. 2H, a second barrier metal film 210, such as titanium (Ti), titanium nitride (TiN), or a combination thereof, and a conductive material 222, such as tungsten, is deposited (e.g., by physical vapor deposition or chemical vapor deposition) to fill in the second trench 205 and the via hole 217 shown in FIG. 2G. Subsequently, the conductive material 222 is planarized by CMP to form a second upper metal film 222′ and a via contact 226 of the MIM capacitor as shown in FIG. 2I. Although not shown in FIG. 2H, the second barrier metal 220 may also be deposited in the via hole 217. The width of the second trench 205 may be substantially the same as the width of the first trench 203 (e.g., the width may be in a range of about 50 μm to about 100 μm, such as about 60 μm to about 90 μm, about 65 μm to about 85 μm, or any other value or other range of values therein). However, in some embodiments, the second trench 205 may be slightly narrower than first trench 203 (e.g., by up to about two times the thickness of the dielectric film 208). Additionally, the second upper metal film 222′ may be substantially aligned with first upper metal film 212, and together the second upper metal film 222′ and the first upper metal film 212 form an upper electrode of the MIM capacitor. The depth of metal layer for the second upper metal film 222′ as deposited may be in a range of about 1 μm to 20 μm (e.g., about 2 μm to about 10 μm, about 2.5 μm to about 8 μm, or any value or range of values therein).

As shown in FIG. 2I, although the second upper metal film 222′ formed in the above-described manner is overetched during CMP planarization, as when forming the first upper metal film 212, the second upper metal film 222′ fills any dishing that is present in the first upper metal film 212. Meanwhile, unlike the dishing that occurs in a conventional MIM capacitor electrode, dishing 224 has a comparatively small depth in the second upper metal film 222′ as compared to a conventional MIM capacitor where a deep trench is formed once and is then filled with a metal film. The present two-step trench-forming process thereby significantly reduces the dishing phenomenon.

The present invention includes a method wherein trenches and via holes are formed in a two-step process, and thus the present method may be regarded as similar to a dual damascene method. However, in the present invention, the two trenches are sequentially formed and the via hole is formed separate from the two trenches. Accordingly, the present invention is somewhat different from a dual damascene method.

As described above, in accordance with the embodiments of the invention, an upper metal film (e.g., an electrode) of a capacitor may be formed in a two-step process that includes forming two trenches (one over the other) and sequentially filling the trenches (once formed) with a conductive material. The presently disclosed method(s) of manufacturing the trench structure in an MIM capacitor reduces the extent of and/or prevents the occurrence of a dishing phenomenon in which the upper metal film of the MIM capacitor is excessively etched due to the thickness of the upper metal film as deposited and a large surface area of the MIM capacitor.

While the invention has been described with respect to several embodiments, the present invention is not limited thereto. It will be understood by those skilled in the art that various changes and modifications may be made without departing from the scope of the invention as defined in the following claims.

What is claimed is:

1. A method for manufacturing a trench structure for a MIM capacitor, comprising:
forming a lower metal film on or in an underlying dielectric on a semiconductor substrate;
forming a first inter-metal dielectric on the lower metal film;
forming a first trench in a capacitor region of the first inter-metal dielectric;
sequentially forming a dielectric film and a first barrier metal film along the bottom surface and sidewalls of the first trench;
filling the first trench with a first conductive material to form a first upper metal film;
forming a second inter-metal dielectric on the first upper metal film;
forming a second trench in a capacitor region of the second inter-metal dielectric;
forming a via hole in a via hole region of the second inter-metal dielectric separate from the first upper metal film by a pre-determined distance;
forming a second barrier metal film along the bottom surface and sidewalls of the second trench; and
filling the via hole and the second trench with a second conductive material to form a via contact and a second upper metal film.

2. The method of claim 1, wherein the first trench exposes the lower metal film.

3. The method of claim 1, wherein the second trench exposes the first upper metal film.

4. The method of claim 1, wherein forming the first upper metal film includes planarizing the surface of the first conductive material until an upper surface of the first inter-metal dielectric is exposed.

5. The method of claim 1, wherein said forming the second upper metal film includes planarizing the surface of the second conductive material until an upper surface of the second inter-metal dielectric is exposed.

6. The method of claim 1, wherein the first and second trenches have a width in a range of about 50 μm to about 100 μm.

7. The method of claim 1, wherein the first and second barrier metal films comprise a titanium/titanium nitride film (Ti/TiN).

8. The method of claim 1, wherein the first and second upper metal films comprise tungsten (W).

9. The method of claim 1, wherein the via contact comprises tungsten (W).

10. The method of claim 1, wherein the first conductive material and the second conductive material are a same material.

11. The method of claim 1, wherein the first trench and the second trench are aligned.

12. The method of claim 1, wherein the first inter-metal dielectric and the second inter-metal dielectric comprise a same material.

13. The method of claim 12, wherein the dielectric film comprises a different material from the first inter-metal dielectric and the second inter-metal dielectric.

14. A trench structure for a MIM capacitor comprising:
a lower metal film on or in an underlying inter-metal dielectric on a semiconductor substrate;
a first inter-metal dielectric on the lower metal film;
a first trench in a capacitor region of the first inter-metal dielectric;
a dielectric film in the first trench;
a first barrier metal film on the dielectric film;
a first upper metal film in the first trench and on or over the first barrier metal film;
a second inter-metal dielectric on the first upper metal film;
a second trench in the second inter-metal dielectric over the capacitor region;
a second barrier metal film on the second inter-metal dielectric and in the second trench; and
a second upper metal film in the second trench and over the second barrier metal film.

15. The trench structure of claim 14, further comprising:
a via contact through the second inter-metal dielectric and separate from the first upper metal film by a pre-determined distance.

16. The trench structure of claim 14, wherein the first and second trenches each have a width in a range of about 50 μm to about 100 μm.

17. The trench structure of claim 14, wherein the first and second barrier metal films comprise a titanium/titanium nitride film (Ti/TiN).

18. The trench structure MIM capacitor of claim 14, wherein the first and second upper metal films comprise tungsten (W).

19. The trench structure MIM capacitor of claim 15, wherein the via contact comprises tungsten (W).

20. The trench structure MIM capacitor of claim 14, wherein the dielectric layer is on the lower metal film, and the second barrier metal film is on the first upper metal film.
